(19) United States
(12) Patent Application Publication
(10) Pub. No.: US 2008/0172868 A1
(43) Pub. Date: Jul. 24, 2008

(54) METHOD FOR MANUFACTURING WIRING BOARD AND METHOD FOR MANUFACTURING MULTILAYER WIRING BOARD

(75) Inventor: Tsuyoshi SHINTATE, Sakata-shi (JP)

Correspondence Address: WORKMAN NYDEGGER, 60 EAST SOUTH TEMPLE, 1000 EAGLE GATE TOWER, SALT LAKE CITY, UT, 84111, US

(73) Assignee: SEIKO EPSON CORPORATION, Tokyo (JP)

(21) Appl. No.: 11/937,332

(22) Filed: Nov. 8, 2007

(30) Foreign Application Priority Data
Nov. 13, 2006 (JP) 2006-306257

(51) Int. Cl. H05K 3/36; B23P 17/00

(52) U.S. Cl. 29/830; 29/417; 29/854

(57) ABSTRACT

A method for manufacturing a wiring board having an electronic component disposed on a substrate and an insulating film formed around the electronic component through application of an insulating material, is disclosed. The method includes: cutting off an electronic component forming substrate on which a plurality of the electronic components are formed, after the electronic component forming substrate has been fixed on a supporting member, to individually separate the plurality of the electronic components; performing lyophilic processing on surface of the plurality of the electronic components while the electronic component forming substrate is fixed on the supporting member; and forming an insulating film around an individually separated electronic component, the electronic component being disposed on the substrate in such a manner that the individually separated electronic component is distanced from the supporting member.

### BACKGROUND OF THE INVENTION

1. Technical Field

The present invention relates to a method for manufacturing a wiring board and a method for manufacturing a multilayer wiring board.

2. Related Art

In recent years, electronic components mounted on circuit boards (wiring boards) are made increasingly smaller and, thus, it is expected that wiring boards be made more minute. As a way of forming such a minute wiring structure, techniques to embed a conductive pattern into an insulating film using droplet discharging method are proposed (See, for example, JP-A-2005-327985). Here, a conductive pattern is formed on a substrate and then an insulating material is applied around the conductive pattern using droplet discharging method. In this way the conductive pattern is embedded in an insulating film. Then, on the top surface thereof, another conductive pattern connecting to the above mentioned conductive pattern is formed. A multilayered conductive pattern is formed in this manner, allowing a wiring board to be miniaturized.

On the other hand, electronic apparatuses including, for example, mobile phone handsets are also made increasingly smaller, thereby limiting the mounting space for electronic components on a circuit board. Thus, it is expected that a method for mounting electronic components in a more highly dense manner be provided. Here, the electronic components may be mounted in a similar manner as described above, namely: first disposing a chip component on a substrate and applying an insulating material around the component, thereby embedding the chip component into an insulating film; and then forming interconnection for connection to the chip component, thus forming a wiring board on which chip components are mounted in a highly dense manner.

However, the following problems still exist in the related art method for manufacturing a wiring board. Namely an IC chip fabricated on a semiconductor substrate generally is fluid repellent with respect to the insulating material for forming an insulating film, and this prevents the insulating material from spreading on the side surfaces of the IC chip when the material is applied around the chip. This occasionally produces estrangement between the IC chip and the insulating film, thereby causing breaking of the interconnection formed on the IC chip.

### SUMMARY

An advantage of the invention is to provide a method for manufacturing a wiring board and a method for manufacturing a multilayer wiring board that allow an insulating film to be formed around an IC chip without producing estrangement.

According to one aspect of the invention, there is a method for manufacturing a wiring board in which the wiring board has an electronic component disposed on a substrate and an insulating film formed around the electronic component by application of an insulating material. The method includes: cutting off an electronic component forming substrate having a plurality of the electronic components formed thereon to separate the electronic component forming substrate into individual pieces of the electronic components, after fixing the electronic component forming substrate on a supporting member; performing lyophilic processing on the surfaces of the plurality of electronic components while the electronic component forming substrate is fixed on the supporting member; and forming the above described insulating film around an individually separated electronic component after it has been disposed on the substrate, distancing the electronic component from the supporting member.

This allows an insulating film to be formed around an electronic component without producing estrangement because lyophilic processing has been performed around the electronic component with respect to the insulating material.

In other words, the circumferential surfaces of the electronic component become lyophilic to the insulating material because lyophilic processing is performed on the surface of the electronic component after the electronic component forming substrate has been cut into individually separated pieces of the electronic components. The insulating material spreads on the circumferential surfaces of the electronic components when it is applied to the individually separated pieces of the electronic components after they have been disposed on the substrate. This permits the insulating film to be formed around the electronic component without estrangement, thereby preventing breaking of interconnection of wiring patterns formed on the electronic components.

Here, lyophilic processing is performed after the electronic component forming substrate has been fixed to the supporting member. Therefore, lyophilic processing is not performed on the surfaces in contact with the supporting member of the electronic components. This prevents lyophilic processing from being performed on active faces of the electronic components if their surfaces in contact with the supporting member are made their active faces, and changes in the electric characteristic of the electronic components will be avoided.

It is preferable that the insulating material be applied by droplet discharging method in the step to form the insulating film of the method for manufacturing the wiring board.

According to the aspect of the invention, the insulating material can be selectively applied by droplet discharging method, thereby preventing waste in use of the insulating material and permitting a cost reduction.

Furthermore, in this case, the method for manufacturing the wiring board may include a step to form interconnection units on the insulating film and the electronic components, for connection to the electronic components.

According to the aspect of the invention, the interconnection units can be formed without creating breaking of interconnection because the insulating film is formed around the electronic components without estrangement.

It is preferable that the thickness of the insulating film be the same as the thickness of the electronic components.

The insulating film and the electronic component having the same thickness prevent breaking of interconnection from occurring at the borders between the electronic component and the insulating film with respect to the wiring pattern formed on the electronic components and the insulating film.

The method for manufacturing a multilayer wiring board according to the aspect of the invention may further include laminating the wiring board.

According to the aspect of the invention, in the same way as described above, lyophilic processing with respect to the insulating material is performed around the electronic components, thereby allowing the insulating film to be formed without creating estrangement.

### BRIEF DESCRIPTION OF THE DRAWINGS

The invention will be described with reference to the accompanying drawings, wherein like numbers reference like elements and the contraction scale is appropriately changed in order to show each member in a recognizable size.

FIG. 1 is a sectional view showing a wiring board according to a first embodiment of the invention.

FIGS. 2A through 2C are process drawings showing steps for manufacturing the wiring board according to the first embodiment.

FIGS. 3A through 3C are also process drawings showing a process for manufacturing the wiring board according to the first embodiment.

FIG. 4 is an explanatory diagram showing a cutoff step according to the first embodiment.

FIG. 5 is an explanatory diagram showing lyophilic processing.

FIG. 6 is a sectional view showing a multilayer wiring board that includes the wiring board, according to a second embodiment of the invention.

FIGS. 7A through 7C are process drawings showing a method for manufacturing the multilayer wiring board according to the second embodiment.

FIGS. 8A through 8C are also process drawings showing a method for manufacturing the multilayer wiring board.

FIGS. 9A and 9B are appearance diagrams showing a mobile phone handset that includes the multilayer wiring board.

### DESCRIPTION OF EXEMPLARY EMBODIMENTS

Embodiments of the invention will be described.

### First Embodiment

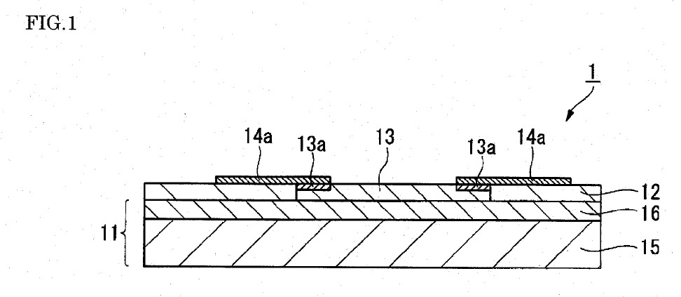

Referring to FIGS. 1A through 5, a method for manufacturing a wiring board according to one embodiment of the invention will now be described.

First, referring to FIG. 1, the wiring board will be described. The wiring board 1 is a circuit board that composes a multilayer wiring board used in, for example, a mobile phone handset (electronic apparatus) to be described later.

The wiring board 1 includes a substrate 11 and an insulating film 12 deposited on the substrate 11. Also, the wiring board 1 includes an IC chip (electronic component) 13 disposed on the substrate 11 and interconnection units 14a and 14b that are formed on the IC chip 13 and the insulating film 12.

The substrate 11 is based on a substrate body 15 that is made of silicon, for example, and an insulating film 16 is formed on the substrate body 15. Here, the material of the substrate body 15 is not limited only to silicon but may be glass, quartz glass, a metal plate or other material.

The insulating film 16 is made of an insulating inorganic material such as SiO₂, SiN, Si₃N₄ or an insulating organic material such as a polyimide resin, an epoxy resin, a polyester resin, a phenol resin, a fluorocarbon resin or a UV cure resin. The substrate 11 has the insulating film 16 as an underlying layer formed on the substrate body 15, but it may have an underlying layer of a semiconductor film, a metal film or an organic film, or it may have no underlying layer.

The insulating film 16 is made of a similar material as the insulating film 12, thus enclosing the IC chip 13. In addition, the insulating film 16 has a thickness equal to the thickness of the IC chip 13.

The IC chip 13 is fabricated on a semiconductor base and formed by being cut out from a semiconductor wafer (electronic component forming substrate) 21. The surfaces of the IC chip 13, excluding its top surface, are processed so as to become lyophilic to the insulating material of the insulating film 12. In addition, the insulating film 12 is formed around the IC chip 13 with no estrangement.

The IC chip 13, furthermore, has a plurality of terminal units 13a formed on the top surface. One of the plurality of terminal units 13a is in continuity with the interconnection unit 14a while another one is in continuity with the interconnection unit 14b.

The interconnection units 14a and 14b are made of a conductive metal material such as silver and each of the units is formed on both the IC chip 13 and the insulating film 12 in crossing the border between the top surfaces of the two.

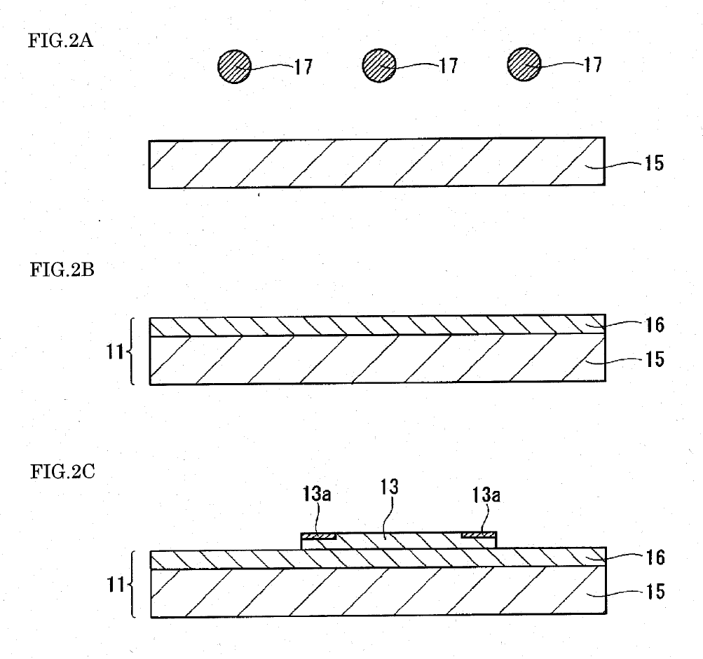

Next, referring to FIGS. 2A through 5, the method for manufacturing the wiring board 1 having the above described structure will now be described.

First, as shown in FIG. 2A, the substrate body 15 is irradiated with ultraviolet rays on the surface, thereby being cleansed and provided with lyophilic processing with respect to an insulating fluid material (insulating material) 17 that forms the insulating film 16, which will be described later. Then, using droplet discharging method, droplets of the insulating fluid material 17 are dropped. The dropped insulating fluid material 17 spreads on the top surface of the substrate body 15. The insulating fluid material 17 that has been applied is subsequently cured. Thus, as shown in FIG. 2B, the insulating film 16 covering the top surface of the substrate body 15 is formed. The substrate 11 is formed in this way.

Here, an inorganic material with insulating property such as SiO₂ or SiN, both forming an insulating film 16 after being dried, or Si₃N₄, or an organic material with insulating property such as a polyimide resin, an epoxy resin, polyester resin, a phenol resin, a fluorocarbon resin or a UV cure resin, is used as the insulating fluid material 17.

It is preferable that the surface tension of the insulating fluid material 17 is within the range of, for example, 0.02 N/m to 0.07 N/m inclusive. If the surface tension is less than 0.02 N/m when droplets are discharged by droplet discharging method, the wettability of the ink compound will increase with respect to the nozzle face, thereby causing deviation to be more easily made in the flight of ink. On the contrary a surface tension exceeding 0.07 N/m will make the meniscus at the nozzle end to be more unstable in shape, thereby making it more difficult to control the quantity discharged and the timing for discharge. In such an occasion, the insulating fluid material 17 may be added with a fluorocarbon, silicone, nonionic or such other surface tension adjuster in a very small amount of a range that will not sharply lower the contact angle with the substrate in order that the surface tension can be controlled. A nonionic surface tension adjuster enhances the wettability of the fluid with respect to the substrate and improves the leveling property of the film, thereby contributing to prevention of micro irregularities produced on the film. The above mentioned surface tension adjuster may contain organic compounds including alcohol, ether, ester, ketone, and the like, as may be required.

It is furthermore preferable that the viscosity of the insulating fluid material 17 be, for example, 1 mPa·s or more and 50 mPa·s or less. This is due to the fact that, when the fluid material is discharged in droplets by droplet discharging method, the portion around the nozzle is easily contaminated by spill of ink if the ink has a viscosity of less than 1 mPa·s while, on the contrary the nozzle hole is often clogged with ink if the ink has a viscosity of more than 50 mPa·s, thereby hampering smooth discharge of droplets.

Here, discharge techniques of droplet discharging method include charge control method, pressure vibration method, electromechanical conversion method, electrothermal conversion method and electrostatic suction method, and the like. The charge control method imparts electric charge to the material at a charging electrode and controls the flight direction of the material at a deflecting electrode in order to discharge the material from the nozzle. The pressure vibration method applies a very high pressure of, for example, around 30 kg/cm² to the material, thereby causing the material to be discharged toward the end of the nozzle. In this case, if no control voltage is applied, the material goes straight ahead to be discharged from the nozzle while, on the other hand, if a control voltage is applied, electrostatic repulsion occurs in the material so that the material spatters and is not discharged from the nozzle. The electromechanical conversion method uses the property of a piezoelectric element to receive pulsed electrical signals and become deformed. Deformation of the piezoelectric element gives pressure through a flexible substance to the space that stores the material, thereby pushing out the material from the space to be discharged from the nozzle. The electrothermal conversion method uses a heater provided in the space storing the material to rapidly vaporize the material and produce bubbles, thereby discharging the material inside the space by pressure of the bubbles. The electrostatic suction method gives a very small amount of pressure into the space storing the material to form a meniscus of the material at the nozzle, applies an electrostatic attraction force in this state, subsequently to draw the material. Other techniques that can be applied include a technique that uses viscous change in the fluid by electric field, a technique that uses discharge sparks to let the material fly and various other techniques. Droplet discharging method is advantageous in that it allows little waste in the use of material and, moreover, allows the material to be disposed at a desired location and in a desired amount. Meanwhile, the amount of one droplet of the insulating fluid material 17 discharged by droplet discharging method is 1 ng or more and 300 ng or less, to give an example.

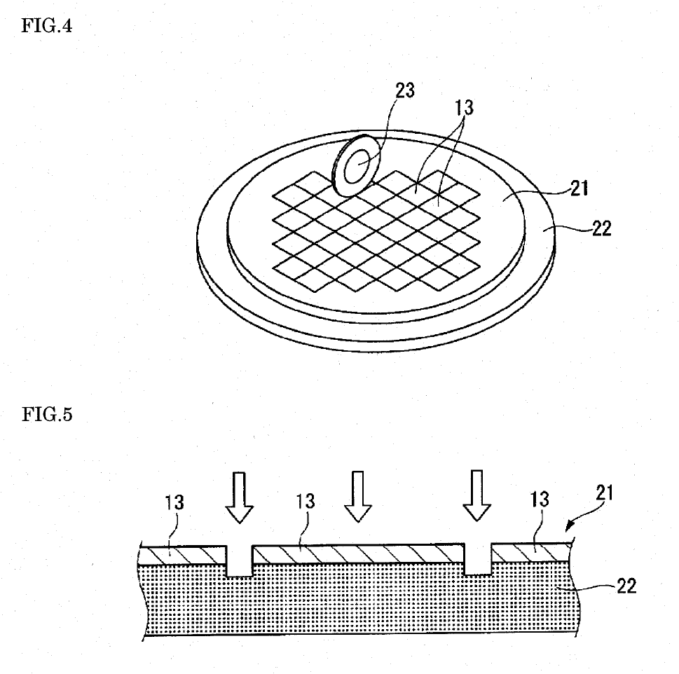

Then, a cutoff step is carried out to cut the semiconductor wafer 21 in accordance with each individual IC chip 13. Here, as shown in FIG. 4, the semiconductor wafer 21 on which a plurality of the IC chips 13 are formed is fixed on a dicing tape (supporting member) 22. Then, the wafer is cut in accordance with each individual piece of the IC chips 13 by the dicing device 23. This separates the plurality of the IC chips 13 into individual pieces in a condition where the chips are still joined together by the dicing tape 22.

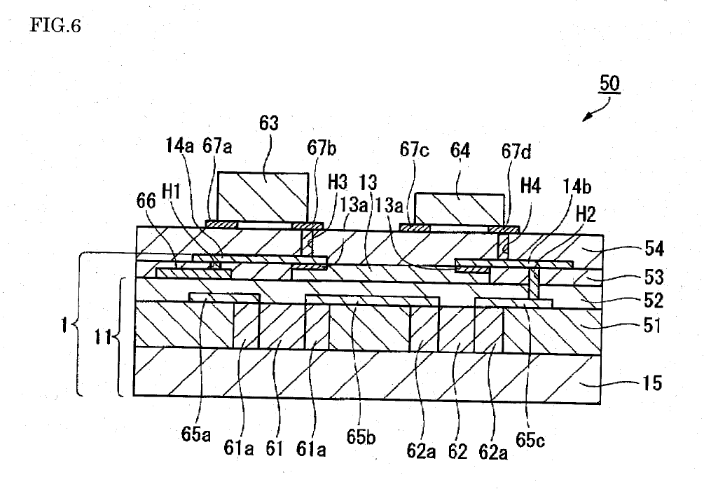

Then, a step to perform lyophilic processing on the IC chips 13 is performed. Here, as shown in FIG. 5, the semiconductor wafer 21 composed of the IC chips 13 is fixed on the dicing tape 22, and, in this way the faces of the IC chips, having no contact with the dicing tape 22, are provided with lyophilic processing to be made lyophilic to the insulating material. There are a variety of ways to perform lyophilic processing, including, for example, application of a_lyophilizer on the surface of the IC chips 13, irradiation of atmospheric pressure plasma, irradiation of excimer UV rays, and the like. The processing renders the faces of the IC chips 13, excluding the faces that are in contact with the dicing tape 22, lyophilic. Therefore if the faces in contact with the dicing tape 22 are used as the active faces of the IC chips, the active faces can be protected from the lyophilic processing, thereby preventing changes in the electric properties of the IC chips 13.

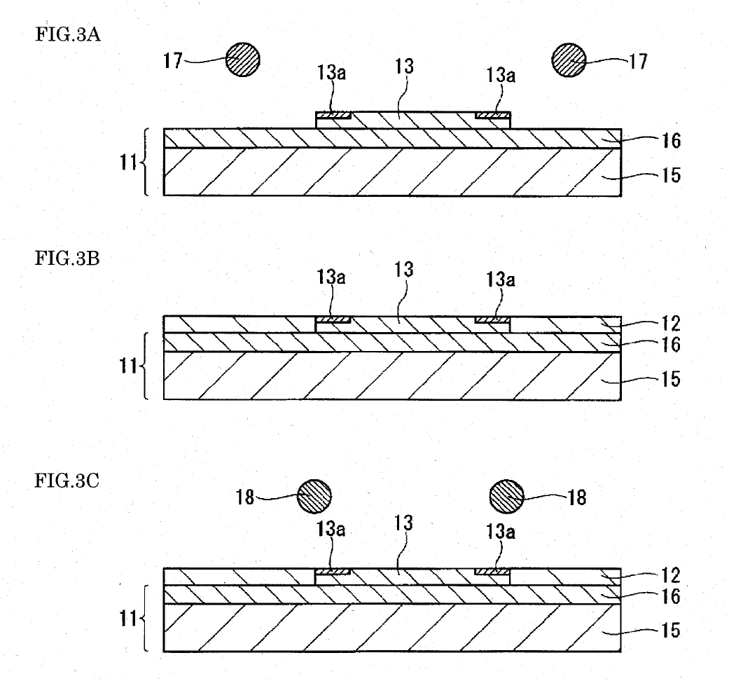

Then, a step to form an insulating film is performed to form an insulating film 12 around the IC chips 13. Here, as shown in FIG. 2C, the IC chips 13 separated into individual pieces and provided with lyophilic processing are each fixed on the substrate 11 using, for example, an adhesive tape. Then, as shown in FIG. 3A, the insulating fluid material 17 is dropped onto portions surrounding the IC chip 13 of the surface of the insulating film 16. Here, the amount of the insulating fluid material 17 to be dropped is such that the insulating film 12 is given a thickness that is equal to the thickness of the IC chip 13. When the insulating fluid material 17 is dropped, it spreads on the top surface of the insulating film 12 because its surface surrounding the IC chip 13 has been made lyophilic to the insulating fluid material 17. The insulating fluid material 17 applied is then cured. Thus, as shown in FIG. 3B, the insulating film 12, covering the surface surrounding the IC chip 13 without estrangement, is formed.

Here, as the insulating fluid material 17, a fluid material that forms the insulating film 12 after being cured, in the same way as in the case of the insulating fluid material 17, may be used. For example, a fluid material containing an insulating inorganic material such as SiO₂ or SiN, or Si₃N₄, or an insulating organic material such as a polyimide resin, an epoxy resin, a polyester resin, a phenol resin, a fluorocarbon resin or a UV cure resin, may be used. In addition, a very small amount of a surface tension adjuster may be added to the insulating fluid material 17 in order to adjust the surface tension.

Next, an interconnection forming step is performed to form the interconnection units 14a and 14b on the top surfaces of the insulating film 12 and the IC chip 13. Here, as shown in FIG. 3C, the above described droplet discharging device is used to drop an interconnection forming fluid material 18 onto the regions for forming the interconnection units 14a and 14b of the top surfaces of the insulating film 12 and the IC chip 13. The interconnection forming fluid material 18 that has been dropped spreads on the top surfaces of the insulating film 12 and the IC chip 13. Then, the interconnection forming fluid material 18 that has been applied is cured, thereby forming the interconnection units 14a and 14b. The wiring board 1 is formed in the above described manner.

Here, a fluid material of a dispersion medium containing dispersed fine particles of silver with the average particle size of 10 nm, is used as the interconnection forming fluid material 18. In this case, an organic or other substance may be used for coating the surfaces of the silver fine particles in order that they may have a better dispersibility. It is preferable that the particle size of the silver fine particles be 1 nm or more and 100 nm or less. If the particle size is larger than 100 nm, the nozzle may be clogged, whereas a particle size that is smaller than 1 nm will increase the percentage in volume of the coating agent with respect to the fine particles of indium tin oxide (ITO), thereby making the percentage of organic substances excessive within the film obtained.

The dispersion medium may be any if it allows the silver fine particles to be dispersed and cause no flocculation. For example, besides water, an alcohol such as methanol or ethanol, propanol or butanol; a hydrocarbon compound such as n-heptane, n-octane, decane, dodecane, tetradecane, toluene, xylene, cymene, durene, indene, dipentene, tetrahydronaphthalene, decahydronaphtalene or cyclohexylbenzene; an ether compound such as ethylene glycol dimethyl ether, ethylene glycol diethyl ether, ethylene glycol methyl ethyl ether, diethylene glycol dimethyl ether, diethylene glycol diethyl ether, diethylene glycol methyl ethyl ether, 1,2-dimethoxyethane, bis(2-methoxyethyl)ether, or p-dioxane; or a polar compound such as propylene carbonate, γ-buthyrolactone, N-methyl-2-pyrrolidone, dimethyl formamide, dimethyl sulfoxide or cyclohexane, may be used as the dispersion medium. Among these, water, alcohols, hydrocarbon compounds and ether compounds are preferable in that their fine particles are more dispersible and their dispersion liquids are more stable and that they can be more easily applied to droplet discharging method. A more preferable dispersion medium is either water or a hydrocarbon compound.

Furthermore, a very small amount of the surface tension adjuster described above may be added into the interconnection forming fluid material 18 in order to adjust its surface tension.

Also, a dispersion stabilizer is added to the interconnection forming fluid material 18 in order to prevent flocculation of the silver fine particles from occurring through mutual contact of the particles. As the dispersion stabilizer, an alkylamine or other amine compound is used. The dispersion stabilizer needs to be able to evaporate together with the dispersion medium in the end after it has left the surfaces of the fine metallic particles. Thus, it is preferable that the dispersion stabilizer be such that it has a boiling point that does not exceed 300° C., normally a boiling point of 250° C. or less. To illustrate, if the dispersion stabilizer is an alkylamine, the alkylamine used is of an alkyl group selected from the groups C8 to C18 and has an amino group at the end of the alkyl chain. An alkylamine within the range of C8 to C18 is thermally stable and its vapor pressure at around room temperature is not very high. This makes it preferable to use because of its facility in handling. For example, when the alkylamine is stored at room temperature, it is easy to keep and control its rate of content within a desired range.

### Second Embodiment

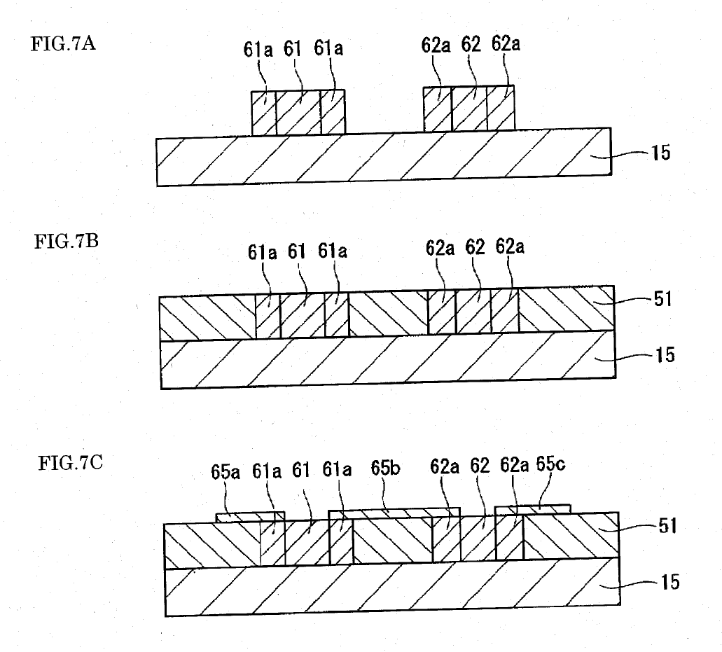

Referring to FIGS. 6 through 10, a method for manufacturing a multilayer wiring board according to another embodiment of the invention will now be described.

First, referring to FIG. 6, the multilayer wiring board will be described.

As shown in FIG. 6, the multilayer wiring board 50 includes a substrate body 15 and insulating films 51 to 54 that are deposited one by one on the surface of the substrate body. The multilayer wiring board 50 also includes a chip resistance 61 and a chip condenser 62 that are disposed on the substrate body 15, an IC chip 13 disposed on the insulating film 52 and a chip antenna 63 and a chip component 64 that are disposed on the insulating film 54. The multilayer wiring board 50 further includes interconnection units 65a through 65c formed on the insulating film 51, an interconnection unit 66 formed on the insulating film 52, interconnection units 14a and 14b formed on the insulating film 53 and interconnection units 67a through 67d formed on the insulating film 54.

The insulating films 51 through 54 are made of an insulating inorganic material such as SiO₂, SiN or Si₃N₄ or an insulating organic material such as a polyimide resin, an epoxy resin, a polyester resin, a phenol resin, a fluorocarbon resin, a UV cure resin.

The insulating film 51 has a thickness that is equal to the thickness of the chip condenser 62. The insulating film 52 is formed so as to cover the interconnection units 65a through 65C formed on the insulating film 51. The insulating film 53 has a thickness that is equal to the thickness of the IC chip 13 and is formed in such a manner that it covers the interconnection unit 66 formed on the insulating film 52. The insulating film 54 is formed so as to cover the interconnection units 14a and 14b formed on the insulating film 53.

In the multilayer wiring board 50, the substrate 11 is composed of the substrate body and the insulating films 51 and 52. Furthermore, the wiring board 1 is composed of the substrate 11, the insulating film 53, the IC chip 13 and the interconnection units 14a and 14b.

Electrodes 61a and 62a are formed at both ends of the chip resistance 61 and the chip condenser 62, respectively. The circumferential surfaces of the chip resistance 61 and the chip condenser 62 are covered by the insulating film 51.

Conductive parts (illustration omitted) are formed on the undersurface of the chip antenna 63 to connect it to the interconnection units 67a and 67b.

Further conductive parts (illustration omitted) are formed on the undersurface of the chip component 64 to connect it to the interconnection units 67c and 67d.

The interconnection units 65a through 65c, 66 and 67c and 67d are made of a metallic material such as silver, in the same way as in the case of the interconnection units 14a and 14b.

The interconnection unit 65a is formed over the top surface of one of the electrodes 61a of the chip resistance 61 and the top surface of the insulating film 51 and is continuous with the one of the electrodes 61a of the chip resistance 61. The interconnection unit 65b is formed over the top surface of the other of the electrodes 61a of the chip resistance 61, the top surface of the insulating film 51 and the top surface of one of the electrodes 62a of the chip condenser 62 and is continuous with the other of the electrodes 61a of the chip resistance 61 and the one of the electrodes 62a of the chip condenser 62. The interconnection unit 65c is formed over the top surface of the other of the electrodes 62a of the chip condenser 62 and the top surface of the insulating film 51 and is continuous with the other of the electrodes 62a of the chip condenser 62.

The interconnection unit 66 is formed on the insulating film 52 and is continuous, through a contact hole H1 running through the insulating film 53, with the interconnection unit 14a formed on the insulating film 53.

The interconnection unit 67a is continuous with the chip antenna 63. The interconnection unit 67b is continuous with the chip antenna 63 and also with the interconnection unit 14a formed on the insulating film 53 through a contact hole H3 that runs through the insulating film 54. The interconnection unit 67c is continuous with the chip component 64. Additionally the interconnection unit 67d is continuous with the chip component 64 and also with the interconnection unit 14b formed on the insulating film 53 through a contact hole H4 that runs through the insulating film 54.

In the multilayer wiring board 50, the interconnection units 65a through 65c, 66, 14a and 14b, and 67c and 67d are laminated, with the insulating films 51 through 54 respectively inbetween, thereby forming a multilayer wiring structure.

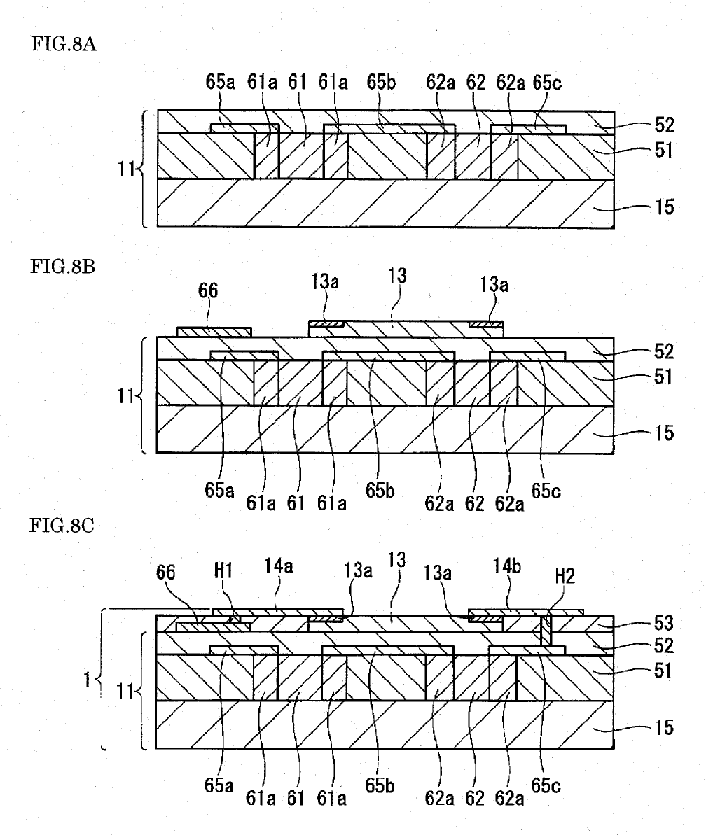

Next, referring to FIGS. 7 through 9, the method for manufacturing the multilayer wiring board will be described.

First, as shown in FIG. 7A, the chip resistance 61 and the chip condenser 62 are fixed on the substrate body 15 by for example, an adhesive tape.

Then, as shown in FIG. 7B, the insulating film 51 is formed around the chip resistance 61 and the chip condenser 62. Here, in the same way as in the case of the insulating film 12 described above, droplet discharging method is used to apply the insulating fluid material 17 in such a way that the film obtained has the same thickness as that of the chip resistance 61 and the chip condenser 62. Then, the material applied is cured and, in this way the insulating film 51 that covers the surrounding areas of the chip resistance 61 and the chip condenser 62 is formed.

Then, as shown in FIG. 7C, the interconnection units 65a through 65c are formed on the top surfaces of the insulating film 51, the chip resistance 61 and the chip condenser 62. Here, in the same way as in the case of the interconnection units 14a and 14b described above, droplet discharging method is used to apply the interconnection forming fluid material 18. The material applied is then cured and, in this way the interconnection units 65a through 65c are formed on the top surfaces of the insulating film 51, the chip resistance 61 and the chip condenser 62.

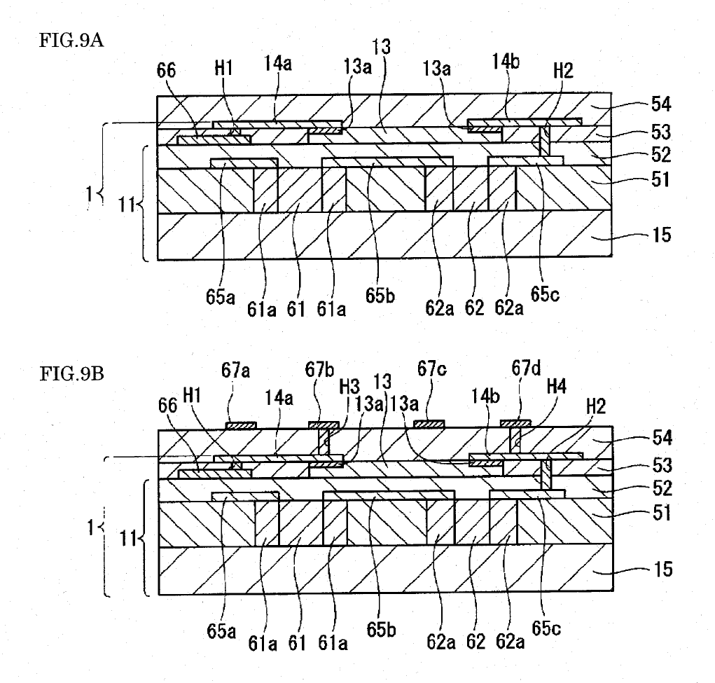

Then, as shown in FIG. 8A, the insulating film 52 that covers the interconnection units 65a through 65c is formed. Here, in the same manner as described above, the insulating fluid material 17 is applied by droplet discharging method. The material applied is then cured and, in this way the insulating film 52 that covers the interconnection units 65a through 65c is formed.

Then, as shown in FIG. 8B, the IC chip 13 is disposed and the interconnection unit 66 is formed on the insulating film 52, in the same manner as described above. Then, the insulating film 53 is formed, covering the interconnection unit 66 and the surrounding area of the IC chip 13. Subsequently as shown in FIG. 8C, the interconnection units 14a and 14b are formed on the top surface of the insulating film 53 and the IC chip 13. At this time, the contact hole H1 running through the insulating film 53 and a contact hole H2 running through the insulating films 52 and 53 are first formed before formation of the interconnection units 14a and 14b, in order to make the interconnection units 14a and 66, as well as the interconnection units 14b and 65c, continuous.

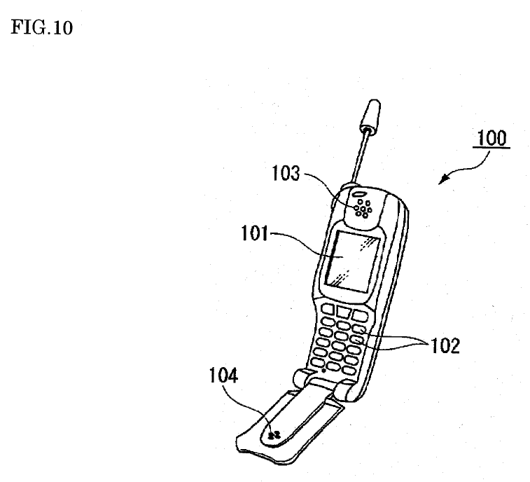

Then, as shown in FIG. 9A, the insulating film 54 covering the interconnection units 14a and 14b is formed. Here, in the same way as described above, the insulating fluid material 18 is applied by droplet discharging method and then cured, thereby forming the interconnection units 14a and 14b.

Then, as shown in FIG. 9B, the interconnection units 67a through 67d are formed on the top surface of the insulating film 54. Here, in the same way as described above, droplet discharging method is used to apply the interconnection forming fluid material 18. The material applied is then cured, thereby forming the interconnection units 67a through 67d on the top surface of the insulating film 54.

Subsequently the chip antenna 63 and the chip component 64 are disposed. The multilayer wiring board 50 shown in FIG. 6 is formed by the above described process.

Among the electronic apparatuses that may house the multilayer wiring board 50 having the above described structure is a mobile phone handset 100 shown in FIG. 10. The mobile phone handset 100 includes a display 101, a plurality of operation buttons 102, an ear piece 103, a mouth piece 104 and a machine body having the above described display 101.

As has been described above, the method for manufacturing the wiring board 1 and the method for manufacturing the multilayer wiring board 50 according to the embodiments of the invention allow the insulation films 12 and 53 to be formed around the IC chip 13 without estrangement if lyophilic processing is applied to the area surrounding the IC chip 13. Therefore, the methods prevent breaking of interconnection from occurring at the borders between the interconnection units 14a and 14b and the insulating films 12 and 53.

Here, lyophilic processing is performed on the semiconductor wafer 21 separated into a plurality of individual IC chips 13 while the wafer is fixed on the dicing tape 22. Therefore, lyophilic processing can be collectively performed on the plurality of individual IC chips 13, thereby simplifying the manufacturing process. Furthermore, the active face of the IC chip 13 brought into contact with the dicing tape 22 is protected from lyophilic processing, thereby allowing the electric characteristic of the IC chip 13 to be maintained. In addition, since the IC chip 13 is disposed on the insulating film 16 or 52 after it has gone through lyophilic processing, the surface of the insulating film 16 or 52 is prevented from being changed in quality through lyophilic processing.

Moreover, the insulating films 16 and 52 having a thickness that is equal to the thickness of the IC chip 13 will more certainly prevent breaking of interconnection occurring at the interconnection units 14a and 14b. Also, the use of droplet discharging method to form the insulating films 16 and 52 will prevent wasteful use of the insulating fluid material 17.

Meanwhile, the present invention is not limited to the above described embodiments. They can be modified in a variety of ways insofar as the modifications do not depart from the spirit and scope of the invention.

For example, whereas an IC chip is used as the electronic component here, some other electronic component may be used as well if only it can be cut off to be made into individual pieces as in the case of the semiconductor wafer.

Whereas a dicing tape is used here to fix the semiconductor wafer on which a plurality of IC chips are formed, some other supporting member may be used as well if only the member has resistance to the cutoff process and the lyophilic rendering process.

Whereas the insulating film covering the surrounding area of the IC chip has a thickness that is equal to the thickness of the IC chip here, the insulating film may have a different thickness if only the interconnection unit connecting to the IC chip can be prevented from breaking of interconnection.

Whereas the IC chip is disposed on an insulating film here, it may be disposed on the underlying layer described above, or it may also be disposed on a substrate body having no underlying layer.

Whereas droplet discharging method is used here to apply the insulating fluid material to form the insulating films here, some other wet process than droplet discharging method, such as spin coat method, may be used to apply the insulating fluid material.

Additionally the multilayer wiring board may also be used in some other electronic apparatus than a mobile phone handset.

What is claimed is:

1. A method for manufacturing a wiring board having an electronic component disposed on a substrate and an insulating film formed around the electronic component through application of an insulating material, the method comprising:
cutting off an electronic component forming substrate on which a plurality of the electronic components are formed, after the electronic component forming substrate has been fixed on a supporting member, to separate the plurality of the electronic components into individual pieces;
performing lyophilic processing on surface of each of the plurality of the electronic components while the electronic component forming substrate is fixed on the supporting member; and
forming an insulating film around an individually separated electronic component, the electronic component being disposed on the substrate in such a manner that the individually separated electronic component is distanced from the supporting member.

2. The method for manufacturing a wiring board according to claim 1, wherein the insulating material is applied by droplet discharging method in forming an insulating film.

3. The method for manufacturing a wiring board according to claim 1, further comprising: forming an interconnection unit on the insulating film and each of the plurality of the electronic components for connection to each of the electronic components.

4. The method for manufacturing a wiring board according to claim 1, wherein the insulating film and the electronic components have equal thickness.

5. A method for manufacturing a multilayer wiring board, comprising:
manufacturing a wiring board according to claims 1; and
laminating the wiring board.
